(19) United States
(12) Patent Application Publication
(10) Pub. No.: US 2013/0257405 A1
(43) Pub. Date: Oct. 3, 2013

(54) ADD-ON BOOST CONVERTER FOR A SOLAR ENERGY SYSTEM

(71) Applicant: ABB OY, Helsinki (FI)

(72) Inventor: Jani KANGAS, Helsinki (FI)

(73) Assignee: ABB Oy, Helsinki (FI)

(21) Appl. No.: 13/850,738

(22) Filed: Mar. 26, 2013

(30) Foreign Application Priority Data
Mar. 27, 2012 (EP) 12161448.1

(51) Int. Cl. G05F 5/00; H05K 13/00

(52) U.S. Cl. CPC G05F 5/00; H05K 13/0023
USPC 323/299; 29/825

(57) ABSTRACT

Exemplary embodiments are directed to a boost converter module for a solar energy system. The boost converter module includes input poles, output poles, and a boost converter unit connected between the input poles and the output poles. The input poles can be adapted for connection to a photovoltaic device feeding an input direct voltage (DC_{IN}). The boost converter unit can be adapted for converting the input direct voltage (DC_{IN}) into an output voltage (V_{OUT}) that is higher than the input direct voltage (DC_{IN}) and to feed the output voltage (V_{OUT}) into the output poles. The module also includes a maximum power point tracking (MPPT) unit, a base, and a lid, and input connection means and output connection means on an inner surface of the base. The lid being adapted for connecting at least one wire to the input poles and the output poles.

### RELATED APPLICATION(S)

This application claims priority under 35 U.S.C. §119 to European application EP 12161448.1 filed in Europe on Mar. 27, 2012, the entire content of which is hereby incorporated by reference in its entirety.

### FIELD

The disclosure relates to solar energy systems, and more particularly to add-on devices for an existing solar energy system.

### BACKGROUND INFORMATION

Large scale solar energy systems consist of arrays of photovoltaic devices, such as photovoltaic cells, connected to an inverter. Shading of a single photovoltaic cell or even a part of it can cause a significant reduction of output power of the whole array and the solar energy system. Dividing the arrays into smaller arrays and adding inverters alleviates the shading problem because the shaded photovoltaic cell will reduce the output power of a smaller array.

One of the challenges associated with the above arrangement is that it is very labour-intensive and expensive to increase efficiency of the system by adding more inverters and renew wiring systems of the photovoltaic cells whenever a photovoltaic cell is shaded. Shading can be caused by e.g. new buildings or growing trees.

### SUMMARY

An exemplary boost converter module for a solar energy system is disclosed, the boost converter module comprising: input poles, output poles and a boost converter unit connected between the input poles and the output poles; a maximum power point tracking (MPPT) unit; a base and a lid; and input connection means and output connection means on an inner surface of the base and the lid for connecting at least one wire to the input poles and the output poles, respectively, wherein the input poles are adapted to be connected to a photovoltaic device feeding an input direct voltage (DC_{IN}), and wherein the boost converter unit is adapted to convert the input direct voltage (DC_{IN}) into an output voltage (V_{OUT}) that is higher than the input direct voltage (DC_{IN}) and to feed the output voltage (V_{OUT}) into the output poles.

An exemplary solar energy system is disclosed, comprising: a photovoltaic cell, an inverter, and a boost converter module, wherein the boost converter module includes: input poles, output poles and a boost converter module connected between the input poles and the output poles; a maximum power point tracking (MPPT) unit; a base and a lid; and input connection means and output connection means on an inner surface of the base and the lid for connecting at least one wire to the input poles and the output poles, respectively, wherein the input poles are adapted to be connected to a photovoltaic device feeding an input direct voltage (DC_{IN}), and wherein the boost converter unit is adapted to convert the input direct voltage (DC_{IN}) into an output voltage (V_{OUT}) that is higher than the input direct voltage (DC_{IN}) and to feed the output voltage (V_{OUT}) into the output poles.

An exemplary method for installing a boost converter module to an existing photovoltaic cell system is disclosed, wherein the boost converter module includes a base and a lid, and input connection means and output connection means on an inner surface of the base and the lid, the method comprising: cutting a direct current wire into a first wire and a second wire; introducing the first wire into the input connection means of the boost converter module; introducing the second wire into the output connection means of the boost converter module; and pressing the lid of the boost converter module against the base of the boost converter module in order to connect said first wire to the boost converter input poles and said second wire to boost converter output poles.

### BRIEF DESCRIPTION OF THE DRAWINGS

In the following the disclosure will be described in greater detail by means of exemplary embodiments with reference to the accompanying drawings, in which

FIG. 1 illustrates an example of a boost converter module lid open in accordance with an exemplary embodiment of the present disclosure; and

FIG. 2 illustrates an example of a boost converter module installed to a wire.

### DETAILED DESCRIPTION

A first exemplary embodiment of the disclosure is a boost converter module for solar energy system. The boost converter module includes input poles, output poles and a boost converter unit connected between the input poles and the output poles. The input poles are adapted to be connected to a photovoltaic device feeding an input direct voltage. The boost converter unit is adapted to convert the input direct voltage into an output voltage that is higher than the input direct voltage and to feed the output voltage into the output poles. The boost converter module includes (e.g., comprises) a maximum power point tracking unit and a base and a lid, and input connection means and output connection means on inner surfaces of the base and the lid for connecting at least one wire to the input poles and the output poles. The inner surfaces of the base and the lid are the surfaces which are against or next to each other when the lid is closed.

In an exemplary embodiment, the boost converter module including a hinge connecting the base and the lid, and the input connecting means and/or the output connecting means is adapted to connect a wire introduced in said means to the boost converter unit when the hinged lid is pressed against the base.

In an exemplary embodiment, the input connection means and/or the output connection means includes crimping means for making a crimped connection with a wire introduced in said means when the hinged lid is pressed against the base.

In another exemplary embodiment, the input connection means and/or the output connection means includes connection needles for penetrating insulation and making a connection with a wire introduced in said means when the hinged lid is pressed against the base.

In an exemplary embodiment, the boost converter module includes a cable cutter for cutting a wire introduced in said boost converter module when the hinged lid is pressed against the base.

According to another exemplary embodiment, the boost converter module is arranged to be powered solely by a photovoltaic device.

In yet another exemplary embodiment disclosed herein, the input connection means and/or the output connection means is a connector.

In an exemplary embodiment of the present disclosure, the boost converter module further includes an inverter unit.

In an exemplary embodiment, the boost converter module further includes means for setting a bypass voltage and means for bypassing the boost converter unit when voltage at the input is higher than the set bypass voltage.

In another exemplary embodiment, the boost converter module further includes means for setting a maximum output voltage.

According to a further exemplary embodiment, the boost converter module includes multiple pairs of input poles and means for joining the input poles in order to combine the input power from multiple input poles in to a single input feed.

An exemplary embodiment of the present disclosure is related to a solar energy system that includes a photovoltaic device and an inverter. The system is wherein it further includes a boost converter module according to the first aspect of the disclosure.

Another exemplary embodiment of the disclosure is related to a method for installing a boost converter module to an installed photovoltaic device system. The method is wherein the boost converter module includes a base and a lid, and input connection means and output connection means between the base and the lid, wherein the method includes the steps of cutting a direct current wire into a first wire and a second wire, introducing the first wire in to the input connection means of the boost converter module, introducing the second wire in to the output connection means of the boost converter module, and pressing the lid of the boost converter module against the base of the boost converter module in order to connect said first wire to the boost converter input poles and said second wire to the boost converter output poles.

In an exemplary embodiment, the cutting of the direct current wire is performed with the boost converter module by pressing the lid of the boost converter module against the base of the boost converter module.

According to another exemplary embodiment of the disclosure a boost converter module is used in implementation in a solar energy system.

An advantageous feature of the arrangement described in the exemplary embodiments of the disclosure is that the presented boost converter module can be easily installed to an existing solar power system without changing any other devices.

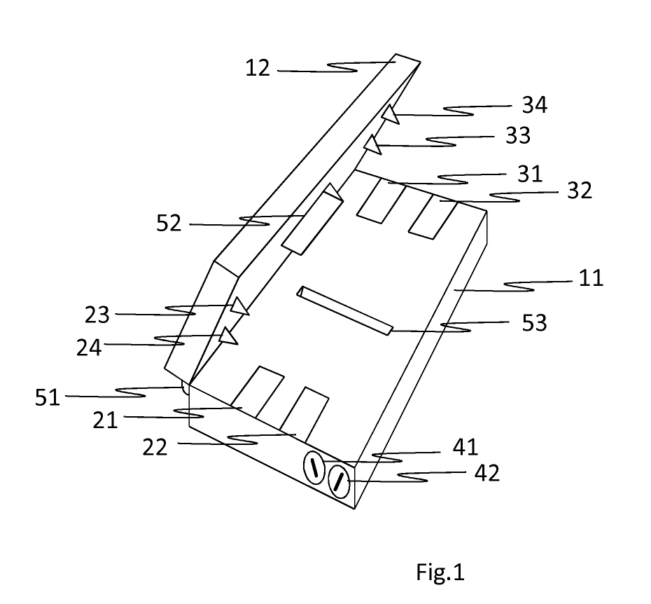

FIG. 1 illustrates an example of a boost converter module lid open in accordance with an exemplary embodiment of the present disclosure. The boost converter module includes (e.g., comprises) a base 11 and a lid 12 and a hinge 51 connecting the base 11 and the lid 12. The hinge 51 enables opening and closing of the lid 12. In another embodiment, there could be multiple hinges or the hinge can be omitted or substituted with some other known means for aligning the lid 12 with the base 11 and locking it therein.

The base 11 includes an input having two input poles 21, 22 for direct voltage (DC) from a photovoltaic device. The base 11 also includes an output having two output poles 31, 32 for direct voltage or alternating voltage, for example, on an opposite edge to the input poles. In an exemplary embodiment, the boost converter module can include multiple pairs of input poles 21, 22 and multiple pairs of output poles 31, 32. Multiple photovoltaic devices or multiple arrays of photovoltaic devices can be connected to a dedicated input in order to achieve optimal output in different conditions. The boost converter module has means for joining the multiple inputs from multiple photovoltaic devices in series or in parallel depending on the input direct voltage DC_{IN} in each of the inputs. The boost converter module is able to provide at least one sufficient output for an inverter device even in poor conditions by joining inputs from multiple photovoltaic devices. In normal conditions, the amount of active outputs can be the same as the amount of active inputs because each of the photovoltaic devices is producing a sufficient amount of power for an inverter device.

In an exemplary embodiment, the boost converter module can be powered solely by photovoltaic devices connected to the input poles. In normal daylight conditions, the photovoltaic device provides enough power to the boost converter module to ensure normal operation and a desired output voltage. At sunset, when the power from the photovoltaic device's output power decreases, the boost converter module deactivates itself and can disconnect itself from the system. When the sun rises again, the boost converter module activates itself again and can connect to the system if it was disconnected. The boost converter module should have much less power to activate than inverter devices, so the boost converter module is already properly functioning by the time the inverter device is activated. The power of the photovoltaic devices at sunrise, when it is not sufficient for the inverter device, could be utilized to warm up and/or ventilate the boost converter module to evaporate any water which might have condensed to the boost converter module during night time. The boost converter module has to function only when power from photovoltaic device is available, therefore other power sources are not specified.

The input poles 21, 22 and/or the output poles 31, 32 can have different physical implementations depending on the specifications and the system where the boost converter module will be installed. For example, the input poles or the output poles can be screw-terminals, DC connectors, proprietary connectors, crimp terminals or pairs of conductors on a circuit board. For example, the physical implementation of the input poles and/or the output poles is such that a wire inserted into input poles or output poles can be connected to the boost converter module by closing the lid 12. In another exemplary embodiment, the input poles and the output poles can be in the lid 12.

The boost converter module includes a boost converter unit connected between the input poles 21, 22 and the output poles 31, 32. The boost converter unit can be on a circuit board which is in the base 11 or the lid 12. In a normal operating mode, the boost controller unit can raise the voltage from the input to the output so that the output voltage is higher than the input voltage. In an exemplary embodiment, the boost converter module's input poles 21, 22 are connected to the boost controller unit's input and the boost controller unit's output is connected to the boost controller module's output poles 31, 32.

The boost converter module can include means for setting different voltage thresholds for the boost converter unit. For example, in an exemplary embodiment the boost converter module can include at least means (e.g., a device) 41 for setting a bypass voltage and means (e.g., device) for bypassing the boost converter unit when voltage at the input is higher than the set bypass voltage. The boost converter module can also include means 42 for setting a maximum output voltage. In an exemplary embodiment, the means for setting voltage threshold can be implemented as dedicated trimmer 41, 42 for each voltage. Also a slide switch, a set of buttons or similar arrangements can be used instead of trimmers. In an exemplary embodiment the trimmers can be substituted with a communication port for connecting to a computing device so that the settings can be made with e.g., a computer or mobile phone connected to the boost converter. The communication port can be realized with, for example, a serial, parallel, Ethernet or universal serial bus (USB) port, or the communications port is implemented to the input poles 21, 22 or the output poles 31, 32 of the boost converter module.

In an exemplary embodiment, the boost converter module includes a maximum power point tracking (MPPT) unit in connection with the boost converter unit. The MPPT unit and the boost converter unit together are capable of drawing maximum power from photovoltaic cells using a wide input voltage range for producing a proper output for e.g., an inverter. The boost controller output can be connected to an inverter device and in another exemplary embodiment the boost converter module can also include an inverter for producing AC power in a small scale.

The base 11 can include one or more slots 53 or cavities and the lid 12 can include one or more cutters 52, e.g. a blade. The blade 52 of the lid 12 protrudes to the slot 53 of the base 11, and the blade and slot combination is adapted to cut an electric wire between the blade and the slot when the lid 12 is closed. In an exemplary embodiment, the lid 12 includes two blades 52 and the base 11 two slots 53 for the blades. When the lid is open, the boost converter module can be introduced around a wire. When the lid is closed, the wire inside the boost converter module can be cut close to both input poles and output poles, and the closing of the lid also connects the cut ends of the wire to the input poles and the output poles.

The boost converter module includes input connection means (e.g., device) 23, 24 and output connection means (e.g., device) 33, 34 between outer surfaces of the base 11 and the lid 12, for example, on the inner surfaces of the base 11 and the lid 12, for connecting wires to the input poles 21, 22 and the output poles 31, 32. The input connection means can include the input poles 21, 22 and the output connection means can include the output poles 31, 32. The input connection means and the output connection means can be located on the inner surface of the base 11 and the lid 12. In an exemplary embodiment of FIG. 1, the lid includes needles 23, 24 as input connection means and needles 33, 34 as output connection means. When the lid 12 is closed, the needles penetrate an insulation of wire inserted to the input poles and/or the output poles and connect the wire electrically to the boost converter module. In another exemplary embodiment, input connection means and/or output connection means include means for making a crimp connection with a stripped wire end when the base 11 and the lid 12 are pressed together. In this case, for example the input poles 21, 22 and the input connection means 23, 24 are arranged to function as a crimper so that a stripped wire end introduced in to the input poles 21, 22 is deformed when the lid 12 is pressed against the base 11. The deforming of the wire fastens it to the input poles 21, 22 and creates an electrical contact from the wire to the boost converter module. The output can have a similar construction for crimping an output wire to the output poles 31, 32.

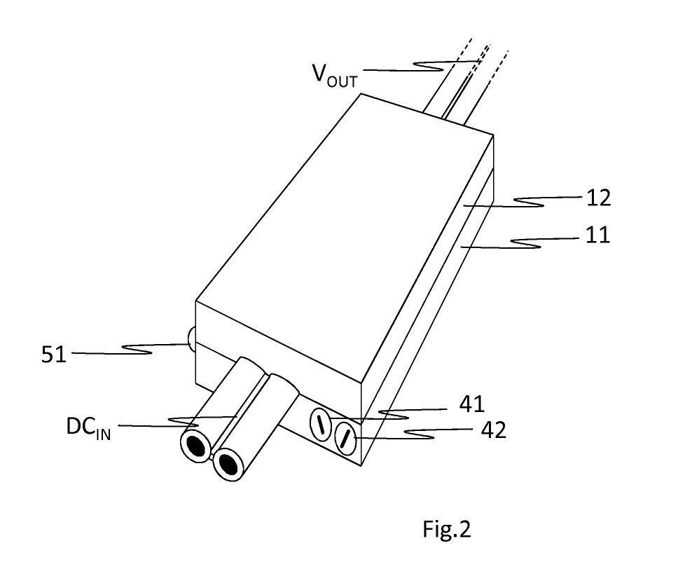

FIG. 2 illustrates an example of a boost converter module installed to a wire. FIG. 2 shows an installed boost converter module having input direct voltage DC_{IN} wire and output voltage V_{OUT} wire connected to the input poles and the output poles, respectively. The boost converter module can be installed to a wire between a photovoltaic cell and e.g., an inverter of a solar energy system. In large-scale systems the photovoltaic cells in arrays and the boost converter module can be installed using a wire between two photovoltaic cells. When installing the boost converter module, the wire in which the module is to be installed can be cut into two wires, a first wire and a second wire. In an exemplary embodiment, the cutting of the wire can be performed with a cutter of the boost converter module.

Next, an open end of the first wire connected to the photovoltaic cell is placed into input connection means of the boost converter module. An open end of the second wire connected to, for example, an inverter, a load or another photovoltaic cell is placed into the output connection means of the boost converter module. When the open ends of the wires are in place, the lid of the boost converter module can be closed by pressing it against the base of the boost converter module. The closing of the lid electrically connects the first wire to the input poles and the second wire to the output poles and also physically connects the wires to the boost converter module.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A boost converter module for a solar energy system, the boost converter module comprising:
input poles, output poles and a boost converter unit connected between the input poles and the output poles;
a maximum power point tracking (MPPT) unit;
a base and a lid; and
input connection means and output connection means on an inner surface of the base and the lid for connecting at least one wire to the input poles and the output poles, respectively,
wherein the input poles are adapted to be connected to a photovoltaic device feeding an input direct voltage (DC_{IN}), and
wherein the boost converter unit is adapted to convert the input direct voltage (DC_{IN}) into an output voltage (V_{OUT}) that is higher than the input direct voltage (DC_{IN}) and to feed the output voltage (V_{OUT}) into the output poles.

2. The boost converter module according to claim 1, comprising:
a hinge connecting the base and the lid,
wherein a wire introduced in the input connecting means and the output connecting means is adapted to be connected to the boost converter unit when the hinged lid is pressed against the base.

3. The boost converter module according to claim 1, wherein the input connection means and the output connection means include crimping means for making a crimped connection with a wire introduced in said means when the hinged lid is pressed against the base.

4. The boost converter module according to claim 1, wherein the input connection means and the output connection means include connection needles for penetrating an insulation and making a connection with a wire introduced in said input connection means and output connection means when the hinged lid is pressed against the base.

5. The boost converter module according to claim 1, comprising:
a cable cutter for cutting a wire introduced in said boost converter module when the hinged lid is pressed against the base.

6. The boost converter module according to claim 1, wherein the input connection means and the output connection means is a connector.

7. The boost converter module according to claim 1, wherein the boost converter module is arranged to be powered solely by a photovoltaic device.

8. The boost converter module according to claim 1, comprising:
an inverter unit.

9. The boost converter module according to claim 1, comprising:
means for setting a bypass voltage and means for bypassing the boost converter unit when voltage at the input is higher than the set bypass voltage.

10. The boost converter module according to claim 1, comprising:
means for setting a maximum output voltage.

11. The boost converter module according to claim 1, comprising:
multiple pairs of input poles and means for joining the input poles to combine input power from the multiple input poles into a single input feed.

12. A solar energy system, comprising:
a photovoltaic cell, an inverter, and a boost converter module, wherein the boost converter module includes:
input poles, output poles and a boost converter module connected between the input poles and the output poles;
a maximum power point tracking (MPPT) unit;
a base and a lid; and
input connection means and output connection means on an inner surface of the base and the lid for connecting at least one wire to the input poles and the output poles, respectively,
wherein the input poles are adapted to be connected to a photovoltaic device feeding an input direct voltage (DC_{IN}), and
wherein the boost converter unit is adapted to convert the input direct voltage (DC_{IN}) into an output voltage (V_{OUT}) that is higher than the input direct voltage (DC_{IN}) and to feed the output voltage (V_{OUT}) into the output poles.

13. The system according to claim 12, wherein the boost converter module includes a hinge connecting the base and the lid, wherein a wire introduced in the input connecting means and the output connecting means is adapted to be connected to the boost converter unit when the hinged lid is pressed against the base.

14. The system according to claim 12, wherein the boost converter module according to claim 1, wherein the input connection means and the output connection means of the boost converter module include crimping means for making a crimped connection with a wire introduced in said means when the hinged lid is pressed against the base.

15. The system according to claim 12, wherein the input connection means and the output connection means of the boost converter module include connection needles for penetrating an insulation and making a connection with a wire introduced in said input connection means and output connection means when the hinged lid is pressed against the base.

16. The system according to claim 12, wherein boost converter module includes a cable cutter for cutting a wire introduced in said boost converter module when the hinged lid is pressed against the base.

17. A method for installing a boost converter module to an existing photovoltaic cell system, wherein the boost converter module includes a base and a lid, and input connection means and output connection means on an inner surface of the base and the lid, the method comprising:
cutting a direct current wire into a first wire and a second wire;
introducing the first wire into the input connection means of the boost converter module;
introducing the second wire into the output connection means of the boost converter module; and
pressing the lid of the boost converter module against the base of the boost converter module in order to connect said first wire to the boost converter input poles and said second wire to boost converter output poles.

18. The method according to claim 17, wherein the cutting of the direct current wire is performed with said boost converter module by pressing the lid of the boost converter module against the base of the boost converter module.
